(19) United States
(12) Patent Application Publication
(10) Pub. No.: US 2014/0131589 A1
(43) Pub. Date: May 15, 2014

(54) ELECTRON BEAM EXPOSURE APPARATUS AND METHOD

(71) Applicant: ADVANTEST CORPORATION, TOKYO (JP)

(72) Inventor: Akio Yamada, Tokyo (JP)

(73) Assignee: ADVANTEST CORPORATION, TOKYO (JP)

(21) Appl. No.: 14/073,600

(22) Filed: Nov. 6, 2013

(30) Foreign Application Priority Data
Nov. 9, 2012 (JP) 2012-247696

(51) Int. Cl. H01J 37/317

(52) U.S. Cl. CPC H01J 37/3174
USPC 250/396 ML; 250/396 R

(57) ABSTRACT

An electron beam EB₀ emitted from an electron gun 101 is cut by a first aperture 103a into a rectangular electron beam DB_{'}, which is then cut by second and third apertures 140a, 150a into an electron beam EB₃ so that the edge cut by the first aperture 103a is removed from the electron beam EB₁. This can prevent blur due to the influence of coulomb interaction of the electron beam EB₁ between the first and second apertures 103a to 140a and perform highly accurate exposure with the electron beam EB₃ having high current density.

### CROSS-REFERENCE TO RELATED APPLICATIONS

This application is based upon and claims the benefit of priority of the prior Japanese Patent Application No. 2012-247696, filed on Nov. 9, 2012, the entire contents of which are incorporated herein by reference.

### TECHNICAL FIELD

The present invention relates to an electron beam exposure apparatus and an electron beam exposure method.

### BACKGROUND ART

Methods for exposing a pattern with electron beams include variable shaped beam (VSB) methods and character projection (CP) methods.

These exposure methods cut an electron beam emitted from an electron gun with a beam shaping section including a rectangular opening and further cut off a part of the cut electron beam with another beam shaping section to provide electron beams shaped into various profiles. The shaped electron beam is then reduced by 20- to 50-fold with an electron lens system and is then projected onto an exposure object.

In order to increase the throughput of exposure in such a process of electron beam exposure, it is effective to increase the range capable of being irradiated with one beam shot to reduce the number of times of beam irradiation and to increase the current density of the electron beam to shorten the exposure time.

However, increasing the area irradiated with an electron beam and the current density thereof can increase the influence of the coulomb interaction between electrons in the electron beam, thus causing a blur of the electron beam. Accordingly, edge roughness of the resist pattern formed by the exposure is increased.

Patent Document 1: Japanese Laid-open Patent Publication No. 2004-88071

Patent Document 2: Japanese Laid-open Patent Publication No. 2001-274077

Patent Document 2: Japanese Laid-open Patent Publication No. 2007-184398

Non-Patent Document 1: “Evaluation of throughput improvement and character projection in multi-column-cell E-beam exposure system”, Akio Yamada et al., Proc of SPIE, Vol. 7748 774816-4

### SUMMARY OF INVENTION

Accordingly, it is an object in one aspect of the invention to provide an electron beam exposure apparatus to minimize the blur of the electron beam even if the current density of the electron beam is increased.

An aspect of the present invention provides an electron beam exposure apparatus, including: an electron gun configured to emit an electron beam; a first beam shaping portion having a first opening configured to shape the electron beam; a first deflector configured to deflect the electron beam having passed through the first opening; a second beam shaping portion having a second opening configured to allow a part of the electron beam having passed through the first opening to pass through; a second deflector configured to deflect the electron beam having passed through the second opening; a third beam shaping portion having a third opening configured to allow a part of the electron beam having passed through the second opening to pass through; and a controller configured to control the first and second deflectors to prevent an edge of the electron beam formed by the first opening from being included in the electron beam having passed through the third opening, and to allow the electron beam to be shaped by only the second and third openings.

According to the electron beam exposure apparatus of the above aspect, in the process of shaping a fine beam, the current value of the electron beam having passed through the second opening is smaller than that of the original electron beam having passed through the first opening. Accordingly, when the edge of the electron beam formed by the first opening is removed by the second and third beam shaping portions, it is possible to suppress the blur of the electron beam due to the coulomb interaction and to therefore draw fine patterns with high accuracy.

### BRIEF DESCRIPTION OF DRAWINGS

FIG. 1 is a view illustrating a beam shaping section of a VSB-type electron beam exposure apparatus according to the prelude.

FIGS. 2A to 2C are views illustrating a method of shaping an electron beam by the electron beam exposure apparatus of FIG. 1.

FIG. 3 is a diagram showing the magnitude of electron beam blur in a second beam shaping section of the electron beam exposure apparatus of FIG. 1.

FIG. 4 is a view illustrating a beam shaping section of a CP-type electron beam exposure apparatus according to the prelude.

FIGS. 5A and 5B are views illustrating a method of shaping an electron beam by the electron beam exposure apparatus of FIG. 4.

FIG. 6 is a scanning electron micrograph of a line pattern produced by using the electron beam exposure apparatus of FIG. 4.

FIG. 7 is a block diagram of an electron beam exposure apparatus according to a first embodiment.

FIG. 8 is a view illustrating a beam shaping section of the electron beam exposure apparatus of FIG. 7.

FIGS. 9A to 9D are views illustrating a method of shaping an electron beam in the electron optical system of FIG. 8.

FIG. 10 is a flowchart showing an electron beam exposure method according to the first embodiment.

FIG. 11 is a block diagram of an electron beam exposure apparatus according to a second embodiment.

FIG. 12 is a view illustrating a beam shaping section of the electron beam exposure apparatus of FIG. 11.

FIGS. 13A to 13C are views illustrating a method of shaping an electron beam by the electron optical system of FIG. 12.

### DESCRIPTION OF EMBODIMENTS

A description is given of the underlying prelude prior to the description of embodiments.

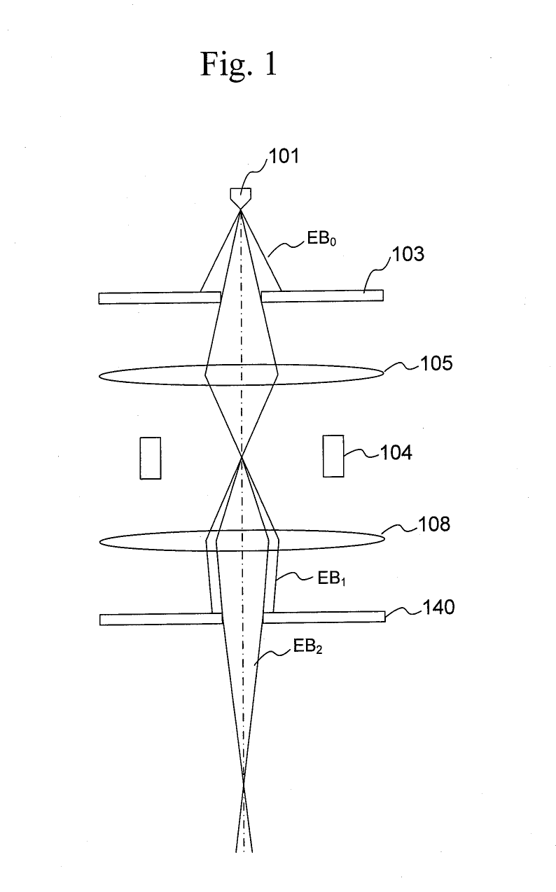

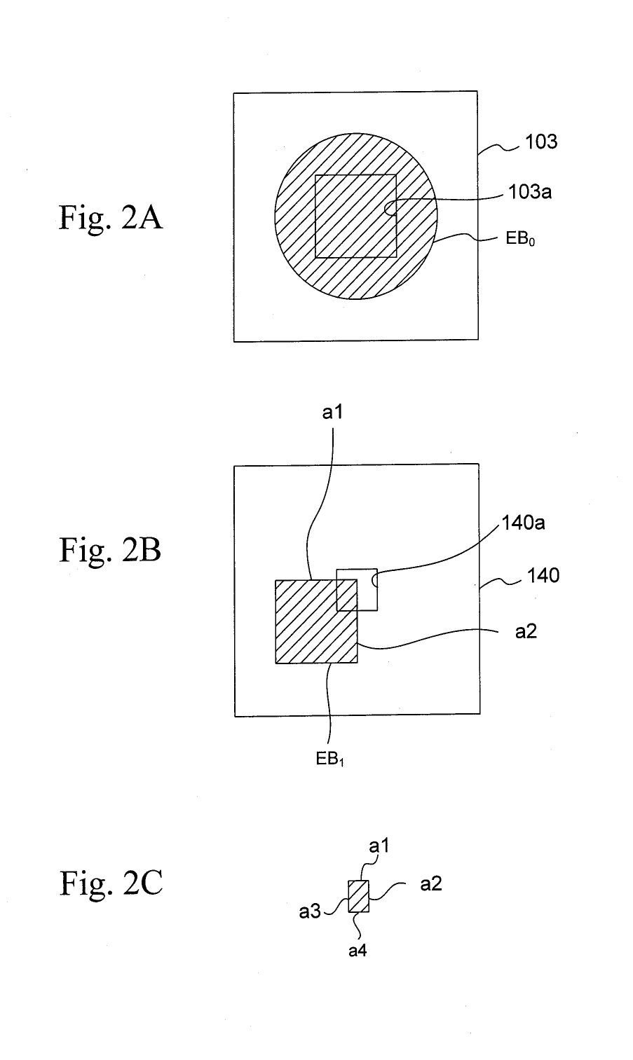

FIG. 1 is a view illustrating a beam shaping section of a VSB-type electron beam exposure apparatus according to the prelude. FIGS. 2A to 2C are view illustrating a method of shaping an electron beam by the electron beam exposure apparatus of FIG. 1.

The beam shaping section of the VSB-type electron beam exposure apparatus shown in FIG. 1 cuts an electron beam EB₀ emitted from an electron gun 101 with a first beam shaping portion 103.

As illustrated by a shaded area in FIG. 2A, the electron beam EB₀ which is emitted from the electron gun 101 and has a circular cross-section is cut out with a first aperture 103 to be shaped into an electron beam EB₁ having a rectangular cross-section (see FIG. 2B). A part of the electron beam EB₀ projected onto other than the first aperture 103a is absorbed or scattered by the first beam shaping portion 103 to be removed.

Next, as illustrated in FIG. 1, the electron beam EB₁ is deflected by a first deflector 104 and is focused onto a second beam shaping portion 140 by electromagnetic lenses 105 and 108.

In this process, a part of the image of the first aperture 103a by the electron beam EB₁ which overlaps a second aperture 140a is clipped as illustrated by a shaded area in FIG. 2B. An electron beam EB₂ having a desired rectangular cross-section is thus obtained as illustrated in FIG. 2C.

The thus-shaped electron beam EB₂ is reduced by 20- to 50-fold with a not-shown electron optical system and is then projected onto the surface of a sample as an exposure object.

As described above, the electron beam EB₂ formed by the beam shaping section of the electron beam exposure apparatus of FIG. 1 includes both an edge cut by the first aperture 103a and an edge cut by the second aperture 140a.

To be specific, edges a1 and a2 of the electron beam EB₂ illustrated in FIG. 2C are edges cut by the first aperture 103a, and edges a3 and a4 thereof are edges cut by the second aperture 140a.

Each edge herein refers to an edge of an image of the corresponding aperture appearing at a cross-section of the focused electron beam.

In order to increase the throughput of the electron beam exposure apparatus, it is required to increase the area irradiated with an electron beam at one shot and to increase the current density of the electron beam. Accordingly, it is necessary to increase the current of the electron beam.

For example, consideration is given to an electron beam which is projected with a size of 1 μm×1 μm at maximum and a current density of 100 A/cm² at the surface of a sample as the exposure object.

In this case, the electron beam EB₁ which passes through the first aperture 103a needs to have the following current based on the current conservation low

1 μm×1 μm×100 A/cm²−1 μA (1)

With such a comparatively large current, the interaction due to coulomb force between electrons included in the electron beam has large influence, thus causing large blur at the edges a1 and a2 of the electron beam EB₁ cut by the first aperture 103a.

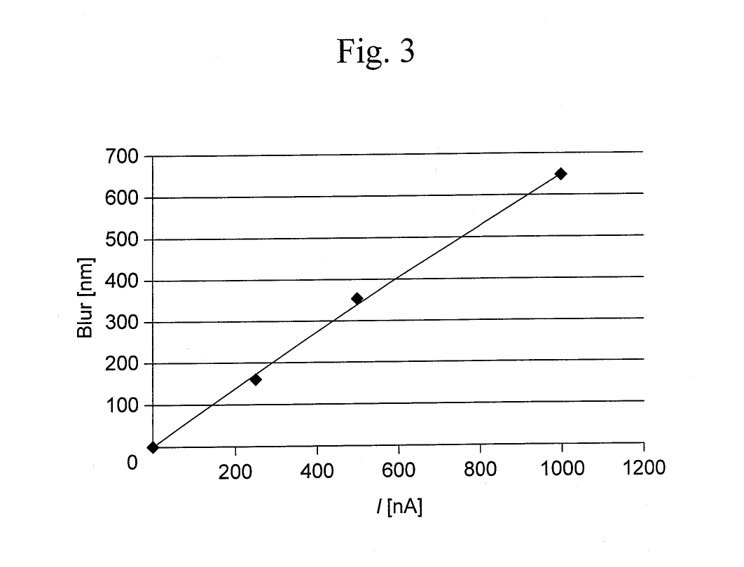

FIG. 3 shows results of calculating the size of blur of the electron beam cut by the first aperture 103a. The horizontal axis thereof shows the current value of the electron beam EB₁, and the vertical axis thereof shows the size of blur. In the calculation of FIG. 3, the distance between the first and second beam shaping portions 103 and 140 is assumed to be about 200 mm.

As shown in FIG. 3, the size of blur of the electron beam EB₁ focused onto the second beam shaping portion 140 increases in proportion to the current value I of the electron beam EB₁. When the current value I is 1 μA (1000 nA), about 650 nm blur occurs at the edge of the electron beam EB₂.

The blur appearing at the second beam shaping portion 140 is reduced by 20- to 50-fold with an electron optical system to be projected onto the surface of the sample, but the size of blur is still 13 to 32 nm on the sample as the exposure object. The blur derived from the electron beam EB₁ cut by the first aperture 103a appears as edge roughness of drawn patterns.

In the case of forming fine patterns with line widths of 11 to 18 nm with the electron beam exposure, for example, it is preferable that the blur at the edge of the electron beam projected onto the sample as the exposure object is less than 10 nm.

Accordingly, it is difficult for an electron beam exposure apparatus including the electron beam shaping section of FIG. 1 to draw patterns having line widths of about 11 to 18 nm when the maximum beam size and current density are 1 μm×1 μm and 100 A/cm², respectively. To draw patterns with line widths of 11 to 18 nm with the aforementioned system, the current density of the electron beam needs to be reduced to about 30 A/cm², and the time required for exposure is therefore increased.

The same problem occurs also in CP-type electron beam exposure apparatus.

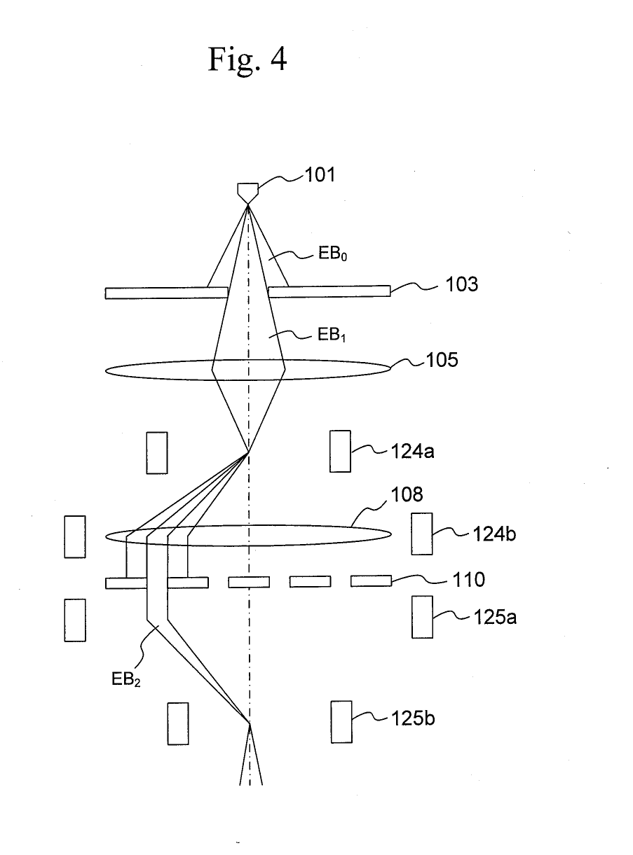

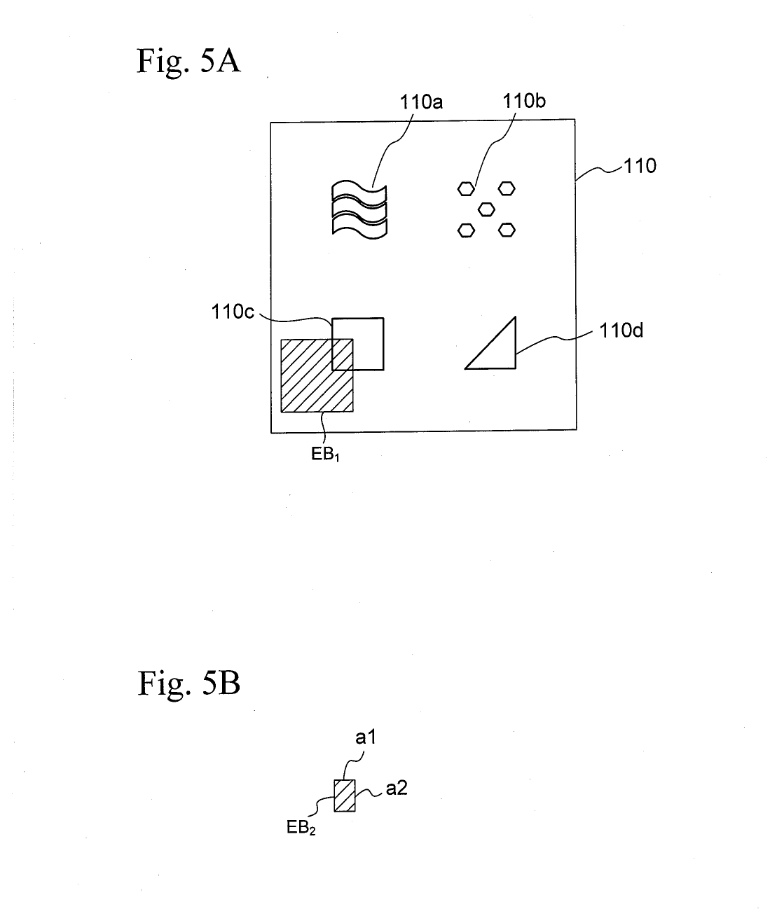

FIG. 4 is a view illustrating a beam shaping section of a CP-type electron beam exposure apparatus according to the prelude. FIGS. 5A and 5B are views illustrating a method for shaping an electron beam in the CP-type electron beam exposure apparatus.

In the beam shaping section of the CP-type electron beam exposure apparatus illustrated in FIG. 4, an electron beam EB₀ emitted from an electron gun 101 is cut by a first beam shaping portion 103 to be shaped into an electron beam EB₁ having a rectangular cross-section.

The electron beam EB₁, which is formed by the first beam shaping portion 103, is positioned by CP mask deflectors 124a and 124b and is then focused onto a predetermined opening pattern of a CP exposure mask 110 by electromagnetic lenses 105 and 108.

As illustrated in FIG. 5A, the CP exposure mask 110 includes a plurality of opening patterns 110a to 110d. The example of the drawing illustrates a part of the CP exposure mask 110, and the CP exposure mask 110 includes several tens to hundreds of opening patterns in total.

In some types of CP exposure process, the size of the electron beam EB₂ is changed by projecting the electron beam EB₁ so that the electron beam EB₁ overlaps a part of the opening pattern 110c as illustrated in FIG. 5B.

In such a case, edges a1 and a2 of the electron beam EB₂ are edges cut by the first beam shaping portion 103 and therefore significantly blur.

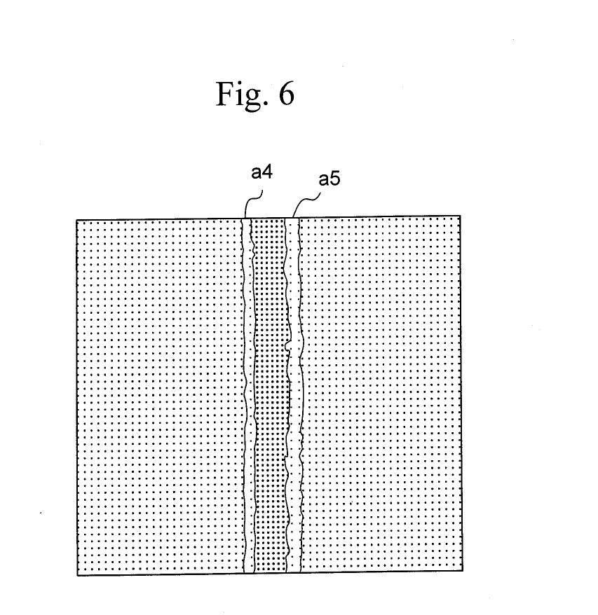

FIG. 6 is a view illustrating a SEM photograph of a linear resist pattern formed with an electron beam shaped using the first aperture 103a and the opening pattern 110c of the CP exposure mask 110.

FIG. 6 shows a result obtained by using the method of FIG. 5A to draw a line pattern with a line width of 60 nm. An edge a4 at the left side of the line pattern in the drawing corresponds to an edge of the electron beam cut by the CP pattern 110c. An edge a5 at the right side of the line pattern corresponds to an edge of the electron beam cut by the first aperture 103a.

In the drawing, the edge a5 at the right side of the line pattern is thicker than the edge a4 at the left side of the line pattern. This shows that the edge roughness of the edge a5 in the width direction is greater than that of the edge a4.

Hereinbelow, embodiments are described.

### First Embodiment

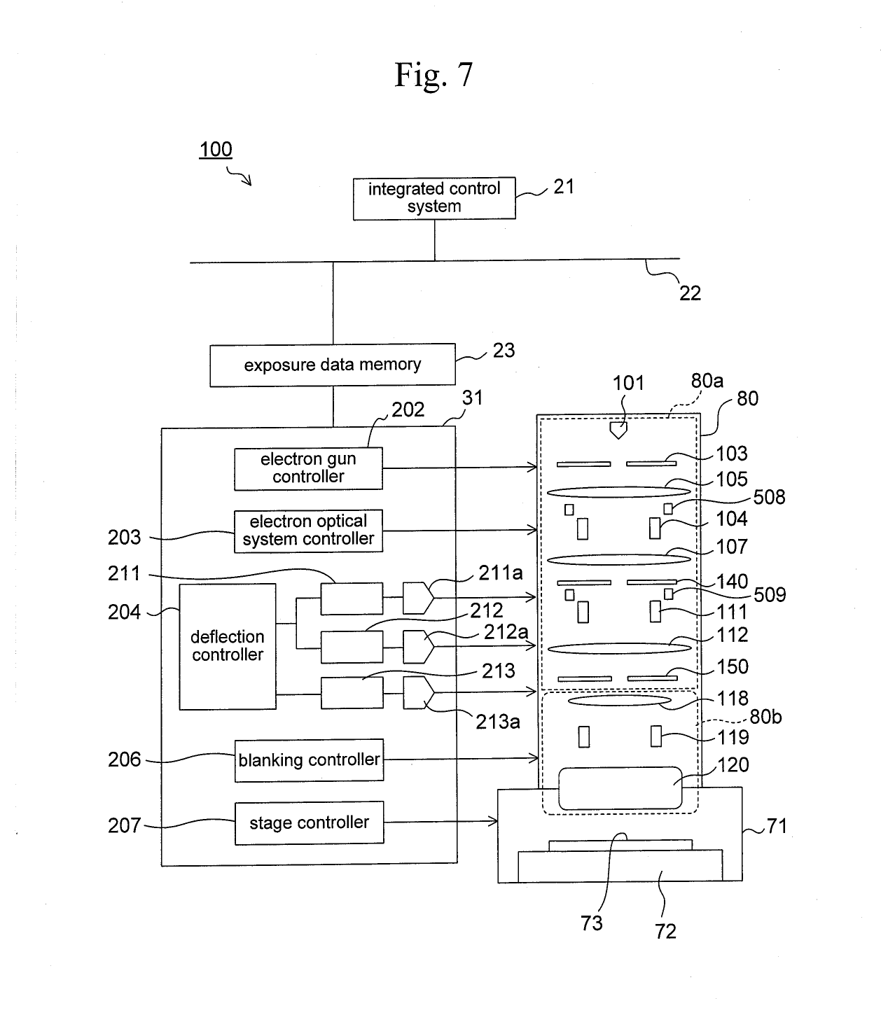

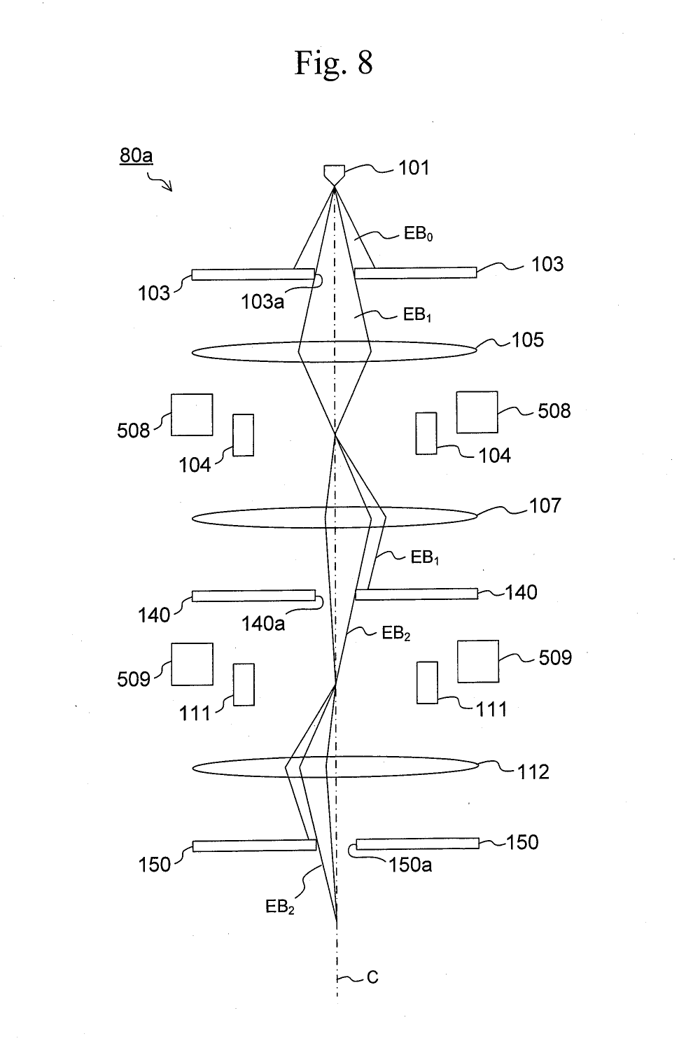

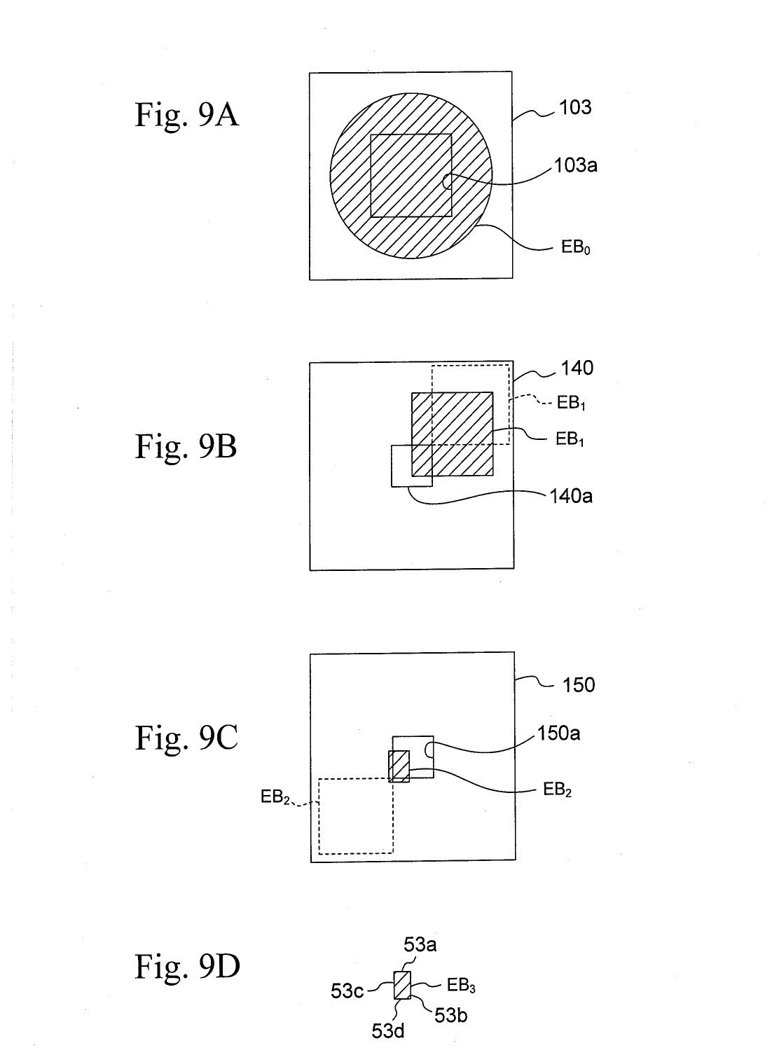

FIG. 7 is a block diagram of an electron beam exposure apparatus according to a first embodiment. FIG. 8 is a view illustrating a beam shaping section of the electron beam exposure apparatus of FIG. 7. FIGS. 9A to 9D are views illustrating a method of shaping an electron beam in the beam shaping section of FIG. 8.

As illustrated in FIG. 7, an electron beam exposure apparatus 100 according to the first embodiment includes an integrated control system 21, an exposure data memory 23, a control section 31, an electron optical system column 80, and a sample chamber 71. The electron optical system column 80 includes a beam shaping section 80a and a substrate deflection section 80b, and the inside thereof has reduced pressure.

As illustrated in FIG. 8, the beam shaping section 80a includes an electron gun 101 configured to emit an electron beam EB₀ and a first beam shaping portion 103 below the electron gun 101 (on the downstream side of the electron beam). The first beam shaping portion 103 is configured to cut the electron beam EB₀. The first beam shaping portion 103 includes a first aperture 103a formed of a rectangular opening as illustrated in FIG. 9A.

As illustrated in FIG. 8, a second beam shaping portion 140 is provided below the first beam shaping portion 103. The second beam shaping portion 140 is configured to cut an electron beam EB₁ which is shaped by the first beam shaping portion 103 to have a rectangular cross-section.

Between the first and second beam shaping portions 103 and 140, first and second electromagnetic lenses 105 and 107 are provided. The first and second electromagnetic lenses 105 and 107 are configured to focus the electron beam EB₁ onto the second beam shaping portion 140 are provided. Moreover, between the first and second electromagnetic lenses 105 and 107, a first deflector 104 and a first alignment portion 508 are provided. The first deflector 104 and first alignment portion 508 are configured to adjust the focusing position of the electron beam EB₁ are provided.

As illustrated in FIG. 9B, the second beam shaping portion 140 includes a second aperture 140a formed of an opening. A part of the electron beam EB₁ overlapping the second aperture 140a passes through the second beam shaping portion 140 into an electron beam EB₂.

Furthermore, as illustrated in FIG. 8, a third beam shaping portion 150 is provided below the second beam shaping portion 140. Between the second and third beam shaping portions 140 and 150, a second deflector 111, a second alignment portion 509, and a third electromagnetic lens 112 are provided.

The electron beam EB₂ is deflected to a predetermined position on the third beam shaping portion 150 by the second deflector 111 and second alignment portion 509 and is focused onto the third beam shaping portion 150 by the third electromagnetic lens 112.

As illustrated in FIG. 9C, the third beam shaping portion 150 includes a third aperture 150a formed of an opening. The third aperture 150a removes the edge cut by the first beam shaping portion 103 among the edge of the electron beam EB₂. Herein, the removal of the edge of the electron beam shaped by the first beam shaping portion 103 refers to preventing a part near the edge in the electron beam having passed through the first beam shaping portion 103 from going to the sample side by reflecting, absorbing, or scattering the part with the beam shaping portions 140 and 150, which are provided on the downstream side.

In the above-described manner, an electron beam EB₃ having a rectangular cross section illustrated in FIG. 9D is obtained.

As illustrated in FIG. 7, the electron beam EB₃ has a cross-section size reduced by 20- to 50-fold by a substrate deflection section 80b and is projected onto a sample 73 which is an exposure object. A fourth electromagnetic lens 118 and an objective lens 120 of the substrate deflection section 80b are configured to focus the electron beam EB₃ onto the sample 73, and an exposure position deflector 119 is configured to deflect the electron beam EB₃ to a desired irradiation position on the sample 73.

The sample chamber 71 is provided with a sample stage 72 movable in the horizontal direction with a motor or the like. The sample 73 as an exposure object is fixed on the sample stage 72. By moving the sample stage 72, the entire surface of the sample 73 can be exposed.

The control section 31 includes an electron gun controller 202, an electron optical system controller 203, a deflection controller 204, a blanking controller 206, and a stage controller 207. The electron gun controller 202 controls the electron gun 101 for control of the acceleration voltage and current density of the electron beam EB₀ and the like.

The electron optical system controller 203 controls the electromagnetic lenses 105, 107, and 112 and the objective lens 120.

The blanking controller 206 controls the voltage to a blanking electrode (not shown) which determines whether to project the electron beam EB₃ to prevent the electron beam EB₃ from being projected onto the sample 73 before exposure.

The stage controller 207 moves the sample stage 72 so that the electron beam EB₃ is projected onto a desired position of the sample 73.

The deflection controller 204 reads exposure data from the exposure data memory 23 and creates beam size data and exposure position data. The beam size data and exposure position data respectively indicate the size of the electron beam and the irradiation position of the electron beam on the sample for each shot.

The deflection controller 204 includes: a first deflection correcting portion 211 and a second deflection correcting portion 212 which operate based on the beam size data; and an exposure position controller 213 which operates based on the exposure position data. The first deflection correcting portion 211 outputs control signals to the first deflector 104 and first alignment portion 508 through a driver 211a. The second deflection correcting portion 212 outputs control signals to the second deflector 111 and second alignment portion 509 through a driver 212a.

The exposure position controller 213 sets a predetermined deflection output to an exposure position deflector 119 through a driver 213a based on the exposure position data.

The exposure data giving an operation instruction to each controller of the control section 31 is created by the integrated control system 21. The integrated control system 21 is a computer, such as a work station, for example. The integrated control system 21 is configured to create exposure data of each shot based on design data indicating a pattern to be exposed. The integrated control system 21 transfers the created exposure data to the exposure data memory 23 through a bus 22.

Hereinbelow, a description is given of operation of the first and second deflection correcting portions 211 and 212.

The first and second deflection correcting portions 211 and 212 respectively set referential outputs to the first and second alignment portions 508 and 509 which correspond to the beam size data of referential beam size (S₀ₓ, S_{0y}). The referential beam size (S₀ₓ, S_{0y}) is a size of a rectangle having a certain magnitude. When the referential outputs are inputted to the first and second alignment portions 508 and 509, an electron beam having the referential beam size (S₀ₓ, S_{0y}) is formed.

For example, as indicated by a dashed line of FIG. 9B, the first alignment portion 508 deflects the electron beam EB₁ so that the lower left corner of the image formed by the electron beam EB₁ on the second beam shaping portion 140 matches the upper right corner of the second aperture 140a.

Moreover, as indicated by a dashed line of FIG. 9C, the second alignment portion 509 deflects the electron beam EB₂ so that the upper right corner of the image formed by the electron beam EB₂ on the third beam shaping portion 150 matches the lower left corner of the third aperture 150a.

The beam size (Sₓ, S_{y}) is therefore set to (0, 0) before the outputs to the first and second deflectors 104 and 111 are set.

The referential beam size (S₀ₓ, S_{0y}) is unnecessarily 0 and may be set equal to the size of the second and third apertures 140a and 150a, for example. In this case, the first deflection correcting portion 211 sets the output for the first alignment portion 508 so that the lower left corner of the image by the electron beam EB₁ on the second beam shaping portion 140 matches the lower left corner of the second aperture 140a. Moreover, the second deflection correcting portion 212 sets the output for the second alignment portion 509 so that the upper right corner of the image by the electron beam EB₂ on the third beam shaping portion 150 matches the upper right corner of the third aperture 150a.

Next, a description is given of a case of increasing the beam size to (Sₓ, S_{y}) when the referential beam size (S₀ₓ, S_{0y}) is 0.

In this case, the first deflection correcting portion 211 sets the predetermined output for the first deflector 104 to deflect the electron beam EB₁ so that the image by the electron beam EB₁ on the second beam shaping portion 140 moves to the lower left with respect to the second aperture 140a. This allows a part of the electron beam EB₂ having a predetermined size to pass through the second beam shaping portion 140 as indicated by the shaded portion of FIG. 9B.

Moreover, the second deflection correcting portion 212 sets a predetermined output for the second deflector 111 to deflect the electron beam EB₂ so that the image by the electron beam EB₂ on the third beam shaping portion 150 moves to the upper right with respect to the third aperture 150a. This forms the electron beam EB₃ having the beam size (Sₓ, S_{y}) as indicated by the shaded portion of FIG. 9C.

On the other hand, when the size of the referential beam size (S₀ₓ, S_{0y}) is equal to the second and third apertures 140a and 150a, the beam size is reduced to (Sₓ, S_{y}) in the following manner.

In this case, the first deflection correcting portion 211 sets the output for the first deflector 104 so that the lower left corner of the image by the electron beam EB₁ on the second beam shaping portion 140 moves to the upper right by a predetermined distance. Moreover, the second deflection correcting portion 212 sets the output for the second deflector 111 so that the upper right corner of the image by the electron beam EB₂ on the third beam shaping portion 150 moves to the lower left by a predetermined distance.

In the case of changing the beam size in this embodiment, as described above, the first and second defectors 104 and 111 are configured to deflect an electron beam in the directions opposite to each other. Accordingly, the electron beam EB₃ can be always prevented from including the edge cut by the first beam shaping portion 103.

As illustrated in FIG. 9D, edges 53a and 53b of the electron beam EB₃ correspond to the edge of the second aperture 140a, and edges 53c and 53d of the electron beam EB₃ correspond to the edge of the third aperture 150a. In other words, the electron beam EB₃ includes the edges cut by the second and third apertures 140a and 150a but does not include the edge cut by the first aperture 103a.

The current value of the electron beam EB₂ passing through the second aperture 140a and the current value of the electron beam EB₃ passing through the third aperture 150a are smaller than the current value of the electron beam EB₁. Accordingly, the coulomb interaction has small influence between the second and third beam shaping portions 140 and 150 and between the third beam shaping portion 150 and the sample 73 as the exposure object.

According to the electron beam exposure apparatus 100 of the first embodiment, it is possible to reduce blur due to the coulomb effect at the edges 53a, 53b, 53c, and 53d of the electron beam EB₃. The surface of the sample 73 can be irradiated with a sharp electron beam having a large current density.

According to the electron beam exposure apparatus 100 of the above-described embodiment, it is possible to increase the exposure throughput while minimizing blur of the electron beam.

Hereinbelow, a description is given of an electron beam exposure method using the electron beam exposure apparatus 100.

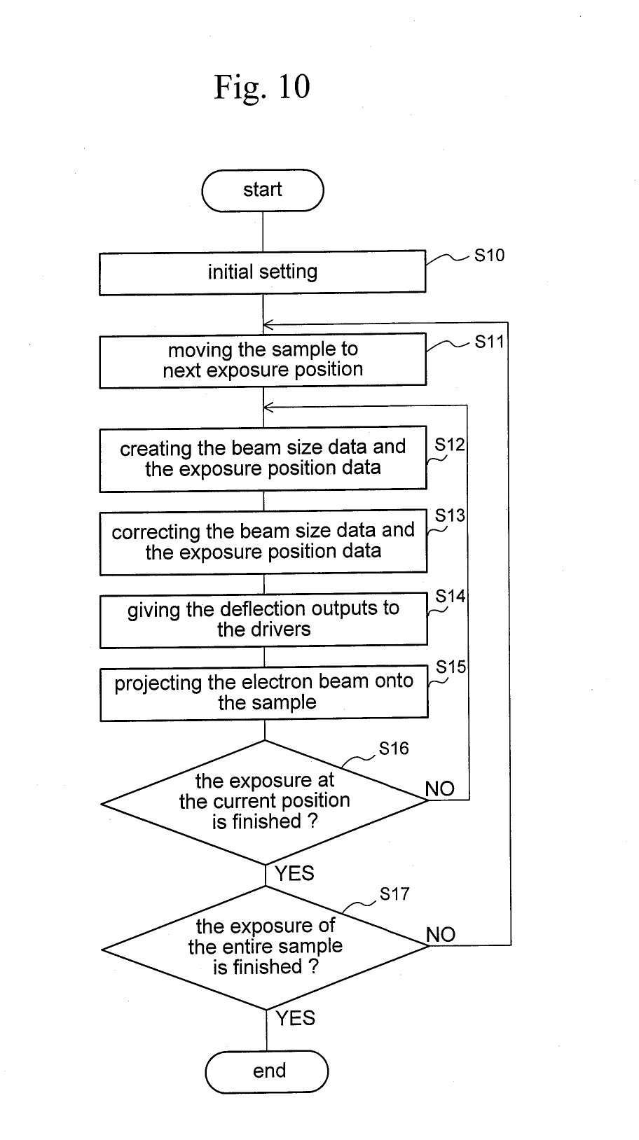

FIG. 10 is a flowchart showing the electron beam exposure method according to the first embodiment.

As illustrated in FIG. 10, the control section 31 (see FIG. 7) of the electron beam exposure apparatus 100 first performs initial setting in step S10 to set the acceleration voltage and current of the electron beam EB₀ to predetermined values. The electron optical system controller 203 supplies predetermined electric powers to the electromagnetic lenses 105, 107, 112, and 118 and the objective lens 120.

Next, the exposure process proceeds to step S11 of FIG. 10. The control section 31 reads initial exposure data from the exposure data memory 23 and uses the stage controller 207 (see FIG. 7) to move the sample 73 to the initial exposure position.

Next, the process proceeds to step S12. Based on the exposure data, the deflection controller 204 of the control section 31 (see FIG. 7) creates the beam size data indicating the size of the electron beam EB₃ to be projected and the exposure position data indicating the coordinates of the irradiation position of the electron beam EB₃.

The process then proceeds to step S13. The first and second deflection correcting portions 211 and 212 of the control section 31 set outputs necessary to output an electron beam of the size specified by the beam size data.

The outputs to the first and second alignment portions 508 and 509 are set by the method previously described with reference to FIGS. 9B and 9C.

The first and second deflection correcting portions 211 and 212 set the outputs for the first and second deflectors 104 and 111 by carrying out the following calculation processing corresponding to coordinate conversion for the inputted beam size data (Sₓ, S_{y}).

The first deflection correcting portion 211 calculates a correction value S₁ₓ in the direction x and a correction value S_{1y} in the direction y for the first deflector 104 based on the following equations.

S₁ₓ=G₁ₓ·(Sₓ−S₀ₓ)+R₁ₓ·(S_{y}−S_{0y})+H₁ₓ·(Sₓ−S₀ₓ)·(S_{y}−S_{0y})+O₁ₓ (1)

S_{1y}=G_{1y}·(S_{y}−S_{0y})+R_{1y}·(Sₓ−S₀ₓ)+H_{1y}·(S_{y}−S_{0y})·(Sₓ−S₀ₓ)+O_{1y} (2)

The second deflection correcting portion 212 calculates a correction value S₂ₓ in the direction x and a correction value S_{2y} in the direction y for the second deflector 111 based on the following equations.

S₂ₓ=G₂ₓ·(Sₓ−S₀ₓ)+R₂ₓ·(S_{y}−S_{0y})+H₂ₓ·(Sₓ−S₀ₓ)·(S_{y}−S_{0y})+O₂ₓ (3)

S_{2y}=G_{2y}·(S_{y}−S_{0y})+R_{2y}·(Sₓ−S₀ₓ)+H_{2y}·(S_{y}−S_{0y})·(Sₓ−S₀ₓ)+O_{2y} (4)

Herein, G is a correction coefficient for the magnification; R, a correction coefficient for the rotational component; H, a correction coefficient for the distortion component; and O, a correction coefficient for the offset component.

(S₀ₓ, S_{0y}) is the referential beam size. When the beam size data (Sₓ, S_{y}) is equal to the referential beam size (S₀ₓ, S_{0y}), the outputs to the first and second deflectors 104 and 111 after the correction calculation are substantially zero. At this time, the outputs for the first and second alignment portions 508 and 509 are set so that the electron beam EB₃ on the sample 73 as the exposure object has a size obtained by reducing the referential beam size (S₀ₓ, S_{0y}) by a predetermined magnification and so that the electron beams are projected onto different corners of the second and third apertures 140a and 150a.

Furthermore, the coefficients G₁ₓ, R₁ₓ, H₁ₓ, G_{1y}, R_{1y}, and H_{1y} and the coefficients G₂ₓ, R₂ₓ, H₂ₓ, G_{2y}, R_{2y}, and H_{2y} are properly set, so that the edge of the electron beam EB₃ on the sample 73 is always formed of only edges cut by the second and third apertures 140a and 150a.

Moreover, in step S13, the exposure position correcting portion 213 calculates a deflection output for the exposure position deflector 119 based on the exposure position data (X, Y) by the following equations. Herein, Xₒᵤₜ and Yₒᵤₜ represent deflection outputs in the directions X and Y for the exposure position deflector 119.

Xₒᵤₜ=gₓ·X+rₓ·Y+hₓ·X·Y+oₓ (5)

Yₒᵤₜ=g_{y}·Y+r_{y}·X+h_{y}·X·Y+o_{y} (6)

Next, the process proceeds to step S14. The drivers 211a, 212a, and 213a of the control section 31 respectively give the deflection outputs corresponding to the correction values calculated by the correcting portions 211, 212, and 213 to the first alignment portion 508 and first deflector 104, the second alignment portion 509 and second deflector 111, and the exposure position deflector 119.

The size and irradiation position of the electron beam EB₃ are thus determined to complete preparation for exposure.

Thereafter, the process proceeds to step S15. The blanking controller 206 of the control section 31 activates a blanker (not shown) only for a predetermined time to project the electron beam EB₃ onto the sample 73.

One beam shot is thus completed.

The process then proceeds to step S16. The control section 31 reads next exposure data from the exposure data memory and determines whether exposure to be performed at the current stage position is finished. In step S16, if the control section 31 determines that the exposure at the current stage position is not finished (NO), the process proceeds to step S12, and the exposure is performed based on the next exposure data.

If the control section 31 determines in step S16 that the exposure at the current stage position is finished (YES), the process proceeds to step S17.

In the next step S17, the control section 31 determines based on the exposure data whether exposure of the entire sample is completed. If the control section 31 determines that exposure for the entire sample is not completed (NO), the process proceeds to the step S11, and the stage controller 207 of the control section 31 moves the sample stage 72 so that the sample 73 is moved to the next stage position.

On the other hand, if the control section 31 determines in the step S17 that exposure for the entire sample is completed (YES), the exposure process is terminated.

In such a manner, electron beam exposure according to the first embodiment is completed.

According to the first embodiment, the edge of the electron beam EB₃ projected onto the sample 73 does not include the edge cut by the first aperture 103a having large blur. Accordingly, the blur of an electron beam can be minimized even if the current density of the electron beam is increased. It is therefore possible to shorten the time of irradiation of the electron beam in the step S15 while maintaining the high accuracy, thus increasing the throughput.

### Second Embodiment

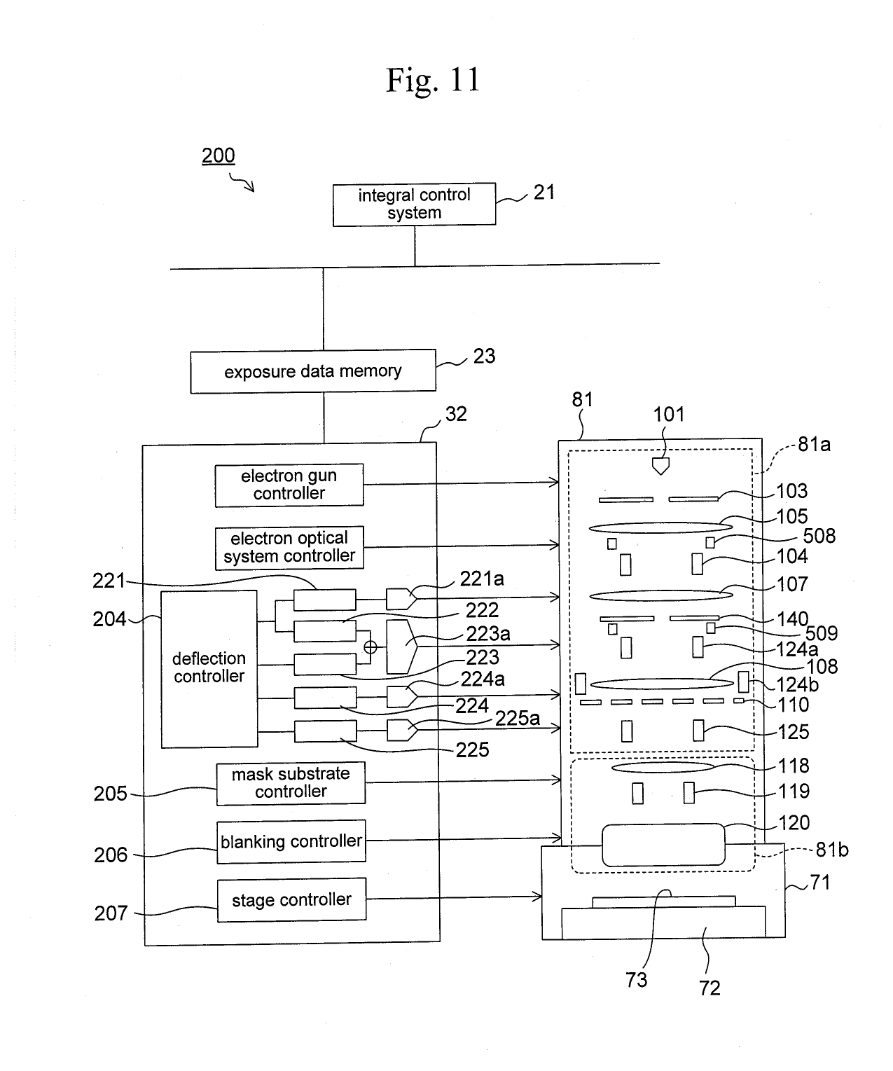

FIG. 11 is a block diagram of an electron beam exposure apparatus according to a second embodiment.

An electron beam exposure apparatus 200 according to the second embodiment differs from the VSB-type electron beam exposure apparatus 100 illustrated in FIG. 7 in terms of being capable of performing the CP-type electron beam exposure. The same structures of the electron beam exposure apparatus 200 of the second embodiment as those of the electron beam exposure apparatus 100 illustrated in FIGS. 7 and 8 are given the same referential numerals, and the detailed description thereof is omitted.

As illustrated in FIG. 11, in the electron beam exposure apparatus 200 according to the second embodiment, a beam shaping section 81a of a column cell 81 includes a first beam shaping portion 103, a first deflector 104, a second beam shaping portion 140, and electromagnetic lenses 105 and 107.

The beam shaping section 81a includes a CP mask 110 having a plurality of opening patterns. CP mask deflectors 124a and 124b are used to select one of the opening patterns in the CP mask 110, and an electron beam EB₃ passes through the selected opening pattern and is then returned to the optical axis by return deflectors 125a and 125b.

An electromagnetic lens 118, an exposure position deflector 119, an objective lens 120, and a sample chamber 71 are the same as those of the electron beam exposure apparatus 100 of FIG. 7.

On the other hand, a control section 32 differs from the control section 31 of FIG. 7 in terms of a deflection controller 204 and a mask substrate controller 205. The mask substrate controller 205 gives a control signal for moving the CP mask 110 to a mask stage holding the CP mask 110 in the case of using an opening pattern located out of the range in which the CP mask deflectors 124a and 124b can deflect.

On the other hand, the deflection controller 204 reads exposure data from an exposure data memory 23 and creates beam size data that specify the beam size of each shot, exposure position data that specify the irradiation position of the electron beam, and CP selection deflection data that specify the opening pattern.

A beam size deflection data correcting portion 221 performs correction calculation for the beam size data, which corresponds to the coordinate conversion to the irradiation position of the electron beam on the second beam shaping portion 140. A beam size deflection data correcting portion 222 performs correction calculation for the beam size data, which corresponds to the coordinate conversion to the irradiation position of the electron beam on the CP exposure mask 110. Moreover, a CP selection deflection data correcting portion 223 performs correction calculation corresponding to the coordinate conversion to the irradiation position on the CP exposure mask 110 based on the CP selection deflection data and sets outputs for the CP mask deflectors 124a and 124b. Furthermore, a CP selection deflection data correcting portion 224 calculates output values to the return deflectors 125a and 125b.

An exposure position data correcting portion 225 performs correction calculation corresponding to the coordinate conversion for the exposure position data.

The calculation results of the aforementioned correcting portions 221, 222, 223, 224, and 225 are outputted through drivers 221a, 223a, 224a, and 225a as driving powers of the deflectors 104, 125, and 119. The calculation results of the beam size deflection data correcting portion 222 and the CP selection deflection data correcting portion 223 are previously added up and inputted to the driver 223a.

Hereinbelow, a description is given of a method of shaping an electron beam by the electron beam exposure apparatus 200.

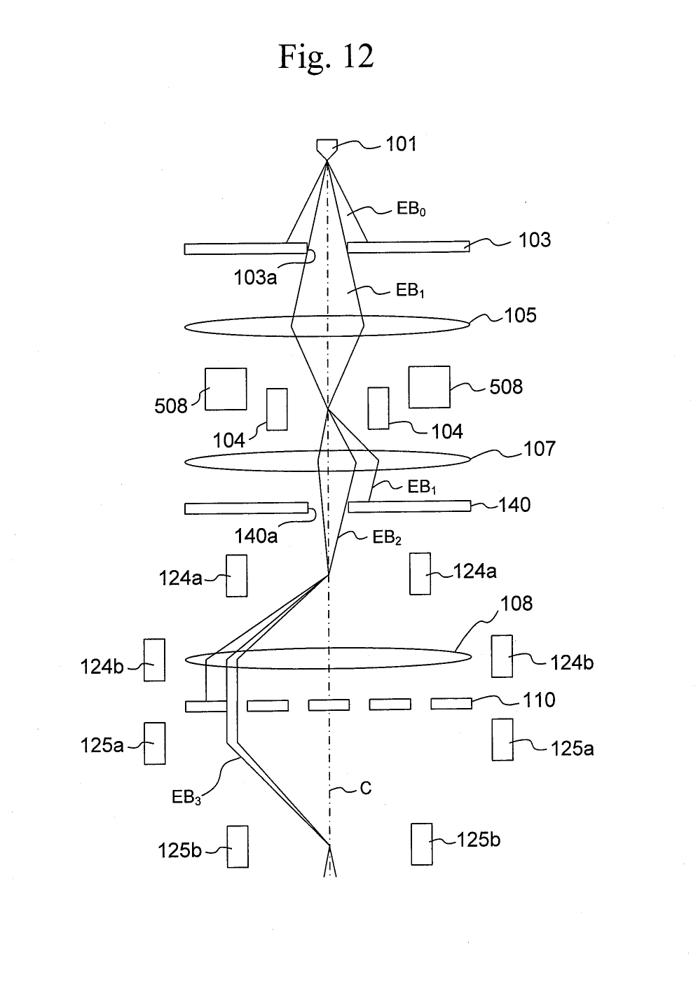

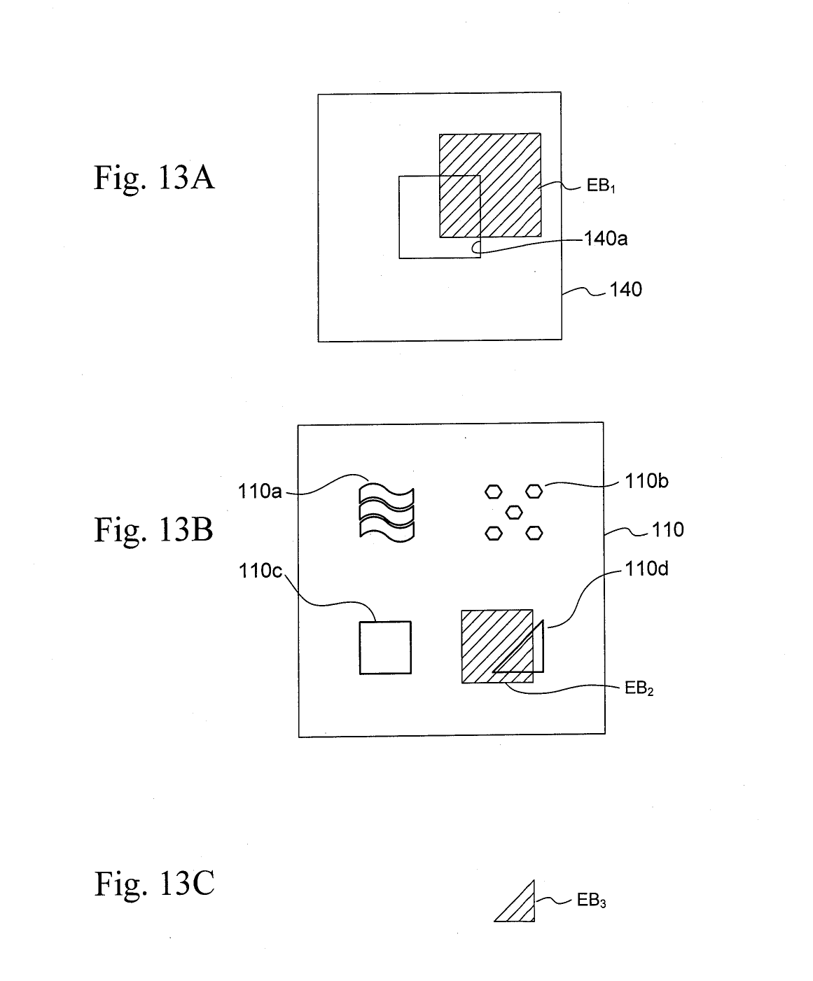

FIG. 12 is a view illustrating the beam shaping section of the electron beam exposure apparatus illustrated in FIG. 11. FIGS. 13A to 13C are views illustrating the method of shaping an electron beam in the beam shaping section of FIG. 12.

As illustrated in FIG. 12, an electron beam EB₀ emitted from an electron gun 101 is cut by the first aperture 103a of the first beam shaping portion 103 to be shaped into an electron beam EB₁ having a rectangular cross-section.

Next, the electron beam EB₁ is guided onto a second aperture 140a of the second beam shaping portion 140 by the first deflector 104 and a first alignment portion 508. The image of a first aperture 103a is formed on the second beam shaping portion 140 by the electromagnetic lenses 105 and 107. A part of the electron beam EB₁ is cut by the second aperture 140a to be shaped into an electron beam EB₂ having a rectangular cross-section as illustrated in FIG. 13A.

As illustrated in FIG. 12, the electron beam EB₂ is guided onto a predetermined opening pattern of the CP exposure mask 110 by the CP mask deflectors 124a and 124b. An image by the electron beam EB₂ is formed on the CP exposure mask 110 by the electromagnetic lens 108. A part of the electron beam EB₂ is cut out by the opening pattern 110d as illustrated in FIG. 13B.

In this embodiment, the size of the electron beam is changed around previously set referential beam size (S₀ₓ, S_{0y}) . To change the beam size (Sₓ, S_{y}), the irradiation position of the electron beam EB₁ on the second beam shaping portion 140, which is moved by the first deflector 104, and the irradiation position of the electron beam EB₂ on the CP exposure mask 110, which is moved by the CP mask deflectors 124a and 124b, are moved in the directions opposite to each other.

As illustrated in FIG. 13C, this provides an electron beam EB₃ having only edges cut by the second aperture 140a and the opening pattern of the CP exposure mask 110. In other words, it is possible to remove the edge cut by the first aperture 103a from the electron beam EB₃.

According to the second embodiment, it is possible to prevent the influence of blur of the electron beam EB₁ and perform highly-accurate exposure with the high current density maintained.

1. An electron beam exposure apparatus, comprising:
an electron gun configured to emit an electron beam;
a first beam shaping portion having a first opening configured to shape the electron beam;
a first deflector configured to deflect the electron beam having passed through the first opening;
a second beam shaping portion having a second opening configured to allow a part of the electron beam having passed through the first opening to pass through;
a second deflector configured to deflect the electron beam having passed through the second opening;
a third beam shaping portion having a third opening configured to allow a part of the electron beam having passed through the second opening to pass through; and
a controller configured to control the first and second deflectors to prevent an edge of the electron beam formed by the first opening from being included in the electron beam having passed through the third opening, and to allow the electron beam to be shaped by only the second and third openings.

2. The electron beam exposure apparatus according to claim 1, wherein the first, second, and third openings are formed in rectangular shapes.

3. The electron beam exposure apparatus according to claim 1, wherein the first and second openings have rectangular patterns, and the third opening has an opening pattern selected from a plurality of opening patterns formed in a mask for CP exposure.

4. The electron beam exposure apparatus according to claim 1, further comprising:
a first electromagnetic lens disposed between the first and second beam shaping portions and configured to focus the electron beam having passed through the first opening onto the second opening; and
a second electromagnetic lens disposed between the second and third beam shaping portions and configured to focus the electron beam having passed through the second opening onto the third opening.

5. The electron beam exposure apparatus according to claim 1, wherein the controller changes an amount of deflection by the first deflector and an amount of deflection by the second deflector in opposite directions to each other around the referential beam size to adjust the size of the electron beam.

6. An electron beam exposure method using an electron beam exposure apparatus that includes: an electron gun configured to emit an electron beam; a first beam shaping portion having a first opening configured to shape the electron beam; a first deflector configured to deflect the electron beam having passed through the first opening; a second beam shaping portion having a second opening configured to allow a part of the electron beam having passes through the first opening passes to pass through; a second deflector configured to deflect the electron beam having passed through the second opening; a third beam shaping portion having a third opening configured to allow a part of the electron beam having passed through the second opening to pass through; and a controller configured to control the first and second deflectors,
the method comprising the steps of, for shaping the electron beam:
using the first deflector to allow the second opening to cut a part of the electron beam having passed through the first opening; and
using the second deflector to allow the third opening to remove an edge formed by the first opening in the electron beam having passed through the second opening.
